(19) United States
(12) Patent Application Publication
(10) Pub. No.: US 2024/0363508 A1
(43) Pub. Date: Oct. 31, 2024

(54) SEMICONDUCTOR MODULE

(71) Applicant: FUJI ELECTRIC CO., LTD., Kawasaki-shi (JP)

(72) Inventor: Hiroyuki NOGAWA, Matsumoto-city (JP)

(73) Assignee: FUJI ELECTRIC CO., LTD., Kawasaki-shi (JP)

(21) Appl. No.: 18/582,880

(22) Filed: Feb. 21, 2024

(30) Foreign Application Priority Data
Apr. 25, 2023 (JP) 2023-071573

(51) Int. Cl. H01L 23/498; H01L 23/31; H01L 25/065

(52) U.S. Cl. CPC H01L 23/49811; H01L 23/3121; H01L 23/3142; H01L 23/49838; H01L 25/0655

(57) ABSTRACT

A semiconductor module includes: a semiconductor element; a housing for housing the semiconductor element, the housing including a terminal hole; a terminal in the terminal hole and being electrically connected to the semiconductor element; a holding member bonded by an adhesive to the housing; and a potting material in the housing, in which the terminal includes a plate-shaped leg between the holding member and the housing including a recess for accommodating the leg, the recess has a depth greater than a thickness of the leg, in the recess, a portion of the leg in a direction of length of the leg is provided with a passage for the adhesive, the passage being across the leg in a direction of thickness of the leg, and a width of the passage is greater than a difference between the depth of the recess and the thickness of the leg.

### CROSS REFERENCE TO RELATED APPLICATION

This Application is based on, and claims priority from, Japanese Patent Application No. 2023-071573, filed on Apr. 25, 2023, the entire contents of which are incorporated herein by reference.

### BACKGROUND

### Technical Field

The present disclosure relates to semiconductor modules.

### Related Art

A semiconductor module, such as a power semiconductor module, generally includes a semiconductor element, a housing for housing the semiconductor element, and a plurality of external terminals electrically connected to the semiconductor element. For example, as described in Japanese Patent Application Laid-Open Publication No. 2017-92388 or in Japanese Patent Application Laid-Open Publication No. 2014-157925, the housing includes a plurality of terminal holes that penetrates the housing. Each of the plurality of external terminals is an external terminal that is inserted into a terminal hole among the plurality of terminal holes. The external terminal includes a terminal portion that protrudes toward the outside of the housing.

In a configuration described in Japanese Patent Application Laid-Open Publication No. 2017-92388, the external terminal further includes an L-shaped leg that protrudes toward the inside of the housing. The L-shaped leg is interposed between the housing and a terminal holding frame. The L-shaped leg, the housing, and the terminal holding frame are bonded to one another.

However, in the configuration described in Japanese Patent Application Laid-Open Publication No. 2017-92388, sufficient adhesive may not enter a gap between the housing and the L-shaped leg. In this case, when a potting material is injected into the housing, the potting material may reach the terminal portion of the external terminal via the gap and the terminal hole, resulting in damage to the external terminal in conductivity.

### SUMMARY

In view of the circumstances described above, an object of one aspect according to the present disclosure is to prevent a potting material (an encapsulation resin) from adhering to a terminal portion of an external terminal.

To solve the above problem, a semiconductor module according to an aspect of the present disclosure includes: a semiconductor element; a housing for housing the semiconductor element, the housing including a terminal hole; an external terminal inserted in the terminal hole, the external terminal being electrically connected to the semiconductor element; a holding member bonded by an adhesive to the housing; and a potting material with which the housing is filled, in which the external terminal includes a plate-shaped leg interposed between the housing and the holding member, the housing includes a recess for accommodating the leg, the recess has a depth greater than a thickness of the leg, a portion of the leg in a direction of a length of the leg is provided with at least one passage for the adhesive in the recess, the at least one passage being across the leg in a direction of thickness of the leg, and a width of the at least one passage in a direction of a width of the leg is greater than a difference between the depth of the recess and the thickness of the leg.

### BRIEF DESCRIPTION OF THE DRAWINGS

FIG. 1 is an exploded perspective view of a semiconductor module according to a first embodiment.

FIG. 2 is a bottom view of a housing.

FIG. 3 is a perspective view of a portion of the housing.

FIG. 4 is a cross section of the semiconductor module taken along line A-A in FIG. 2.

FIG. 5 is a plan view explaining a leg of an external terminal according to the first embodiment.

FIG. 6 is a cross section explaining the leg of the external terminal according to the first embodiment.

FIG. 7 is a diagram explaining a passage for an adhesive in a recess of the housing according to the first embodiment.

FIG. 8 is a flowchart showing a method for producing the semiconductor module according to the first embodiment.

FIG. 9 is a diagram explaining a preparation step.

FIG. 10 is a diagram explaining a terminal insertion step.

FIG. 11 is a diagram explaining an application step in a bonding step.

FIG. 12 is a diagram explaining a bonding together step in the bonding step.

FIG. 13 is a diagram explaining a function of the passage for the adhesive in the bonding together step in the bonding step.

FIG. 14 is a plan view explaining the leg of the external terminal according to a second embodiment.

FIG. 15 is a cross section explaining the leg of the external terminal according to the second embodiment.

FIG. 16 is a diagram explaining the passage for the adhesive in the recess of the housing according to the second embodiment.

### DESCRIPTION OF EMBODIMENTS

Embodiments according to the present disclosure will be described with reference to the drawings. In the drawings, dimensions and scales of elements may differ from those of actual products, and some elements may be shown schematically to facilitate understanding. The scope of the present disclosure is not limited to the embodiments described below unless the following explanation includes a description that specifically limits the scope of the present disclosure.

### 1. First Embodiment

### 1-1. Overall Configuration of Semiconductor Module

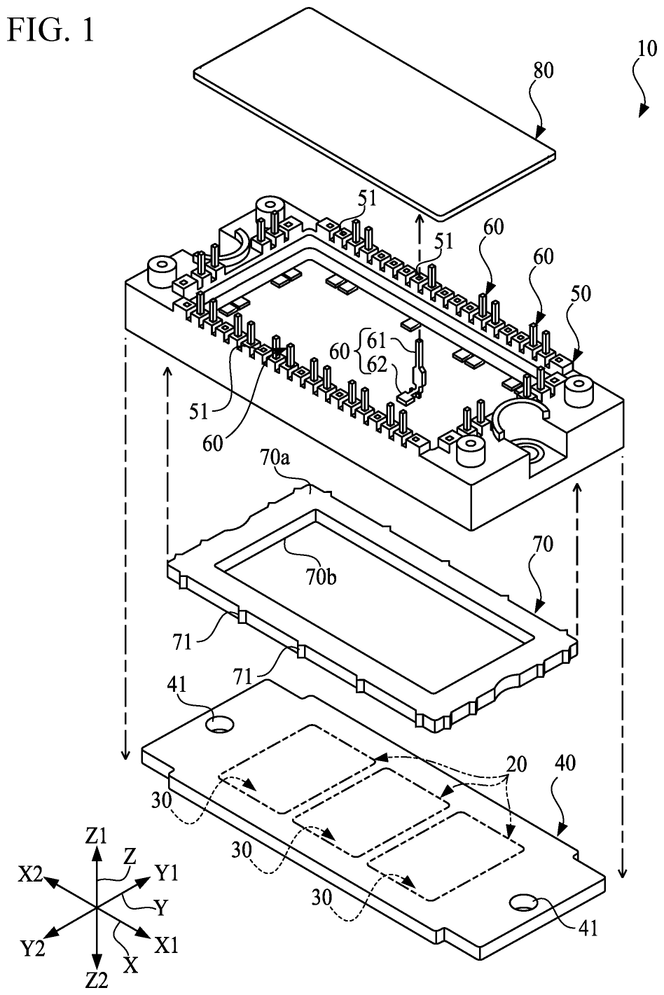

FIG. 1 is an exploded perspective view of a semiconductor module 10 according to a first embodiment. The semiconductor module 10 is a power module such as an insulated gate bipolar transistor (IGBT) module. The semiconductor module 10 is used, for example, to power control a device such as an inverter or a rectifier. The inverter or the rectifier may be disposed on an apparatus such as a railway vehicle, an automobile, or a household electrical machine, etc.

As shown in FIG. 1, the semiconductor module 10 includes a plurality of semiconductor elements 30, a plurality of circuit substrates 20, a base 40, a housing 50, a plurality of external terminals 60, a spacer 70, and a lid 80. The spacer 70 is an example of a “holding member.” In FIG. 1, each of the plurality of semiconductor elements 30 and each of the plurality of circuit substrates 20 are each shown by a thin long-dash, double short-dash line as an outer shape of a circuit substrate 20 of the plurality of circuit substrates 20. Although not shown in FIG. 1, the semiconductor module 10 includes not only elements described above, but also a potting material PA shown in FIG. 4 described below.

First, an outline of each element of the semiconductor module 10 will be described with reference to FIG. 1. For convenience, in the following description, an X-axis, a Y-axis, and a Z-axis are defined that are perpendicular to one another. The Z-axis is an axis parallel to a direction of thickness of the semiconductor module 10. In the following description, a direction along the X-axis is referred to as a direction X1, and a direction opposite to the direction X1 is referred to as a direction X2. A direction along the Y-axis is referred to as a direction Y1, and a direction opposite to the direction Y1 is referred to as a direction Y2. A direction along the Z-axis 10) is referred to as a direction Z1, and a direction opposite to the direction Z1 is referred to as a direction Z2. The relationship between each of these directions and the vertical direction is not particularly limited, and the relationship may be freely selected. In the following description, a view in a direction along the Z-axis may be referred to as a “plan view.”

The circuit substrate 20 is a board on which two or more semiconductor elements 30 of the plurality of semiconductor elements 30 is disposed. The circuit substrate 20 constitutes a circuit together with the two or more semiconductor elements 30. For example, the circuit substrate 20 is a substrate such as a direct copper bonding (DCB) substrate or a direct bonded aluminum (DBA) substrate, etc. Although not shown, the circuit substrate 20 includes an insulating substrate and two conductive layers disposed on both surfaces of the insulating substrate. The insulating substrate is made of, for example, a ceramic material such as an aluminum nitride material, an aluminum oxide material, or a silicon nitride material, etc. Each of the two conductive layers is made of, for example, a metallic material such as a copper material or an aluminum material, etc. One of the two conductive layers is coupled to the plurality of semiconductor elements 30 by a solder material, etc. The other of the two conductive layers is coupled to the base 40 by a solder material, etc.

In the example shown in FIG. 1, a direction of thickness of the circuit substrate 20 is the direction along the Z-axis. The circuit substrate 20 has a surface facing in the direction Z1. The surface of the circuit substrate 20 facing in the direction Z1 is coupled to the two or more semiconductor elements 30 by a conductive bonding material such as a solder material, etc. The circuit substrate 20 further has a surface facing in the direction Z2. The surface of the circuit substrate 20 facing in the direction Z2 is coupled to the base 40 by a conductive bonding material such as a solder material, etc.

The plurality of semiconductor elements 30 disposed on the plurality of circuit substrates 20 includes at least one semiconductor element 30 that is a power semiconductor chip such as an IGBT. The plurality of semiconductor elements 30 disposed on the plurality of circuit substrates 20 may further include, as a semiconductor element 30, a control chip for controlling operation of the power semiconductor chip. Alternatively, the plurality of semiconductor elements 30 disposed on the circuit substrate 20 may further include, as a semiconductor element 30, an element such as a freewheeling diode (FWD) that allows a load current to return.

The base 40 is a plate-shaped member for radiating heat. For example, the base 40 is a metallic plate that is made of a copper material, a copper alloy, an aluminum material, or an aluminum alloy. The base 40 has high thermal conductivity. The base 40 radiates heat conducted from the plurality of semiconductor elements 30. The base 40 further has high electrical conductivity. The base 40 is electrically connected to a reference potential line such as a ground potential line. The base 40 is not limited to a metallic plate. The base 40 may be an insulator with high thermal conductivity.

In the example shown in FIG. 1, a direction of thickness of the base 40 is the direction along the Z-axis. The base 40 is shaped to have a pair of long sides extending in the direction along the X-axis as viewed in the direction along the Z-axis, and a pair of short sides extending in the direction along the Y-axis as viewed in the direction along the Z-axis. The base 40 is provided with a mounting hole 41 in a vicinity of each of the short sides. The mounting hole 41 is a through hole for screwing a heat radiating member such as a heat radiating fin (not shown) to the base 40, for example. The shape of the base 40 in plan view is not limited to the example shown in FIG. 1. The shape of the base 40 in plan view may be freely selected. The base 40 may be replaced with two or more bases 40. The base 40 may be integrally formed together with the circuit substrate 20. In other words, the base 40 may be part of the circuit substrate 20.

The housing 50 is a frame-shaped member that includes a plurality of terminal holes 51. The housing 50 houses the plurality of semiconductor elements 30 disposed on the plurality of circuit substrates 20. The housing 50 is substantially an insulator. The housing 50 is made of a resin material such as a polyphenylene sulfide (PPS) material or a polybutylene terephthalate (PBT) material, etc. The resin material may include an inorganic filler such as an alumina material or a silica material to improve mechanical strength or thermal conductivity of the housing 50.

The plurality of terminal holes 51 are arranged along a circumferential direction of the housing 50. Each of the plurality of terminal holes 51 is a through hole that penetrates the housing 50. In the example shown in FIG. 1, each of the plurality of terminal holes 51 extends in the direction along the Z-axis.

In the example shown in FIG. 1, a direction of thickness of the housing 50 is the direction along the Z-axis. Externally, the housing 50 is shaped to have a pair of long sides extending in the direction along the X-axis as viewed in the direction along the Z-axis, and a pair of short sides extending in the direction along the Y-axis as viewed in the direction along the Z-axis. The plurality of terminal holes 51 of the housing 50 is divided into a plurality of terminal holes 51 arranged along each of the long sides and a plurality of terminal holes 51 arranged along each of the short sides.

In this embodiment, the number of terminal holes 51 of the housing 50 is greater than the number of external terminals 60. The plurality of terminal holes 51 includes a first plurality of terminal holes 51, the number of which is equal to the number of external terminals 60, and a second plurality of terminal holes 51 other than the first plurality of terminal holes 51. In each of the first plurality of terminal holes 51, an external terminal 60 among the plurality of external terminal 60 is inserted. In each of the second plurality of terminal holes 51, no external terminal 60 is inserted. The housing 50, in which the number of terminal holes 51 is greater than the number of external terminals 60, is applicable for use with various semiconductor modules that have different terminal positions. The number of terminal holes 51 and the arrangement of the terminal holes 51 are not limited to the example shown in FIG. 1. The number of terminal holes 51 and the arrangement of the terminal holes 51 may each be freely selected. The number of terminal holes 51 may be equal to the number of external terminals 60.

Each of the plurality of external terminals 60 is a terminal for electrically connecting the plurality of semiconductor elements 30 to a substrate (not shown) on which the semiconductor module 10 is disposed. Each of the plurality of external terminals 60 is inserted in a terminal hole 51 among the plurality of terminal holes 51 so as to be electrically connected to a semiconductor element 30 among the plurality of semiconductor elements 30. Each of the plurality of external terminals 60 is made of, for example, a metallic material such as a copper material, a copper alloy, an aluminum material, an aluminum alloy, or an iron alloy, etc. Each of the plurality of external terminals 60 may have a plated surface such as a surface plated with Sn or a surface plated with Sn—Cu, etc.

The plurality of external terminals 60 of the semiconductor module 10 includes a first plurality of external terminals 60 and a second plurality of external terminals 60 other than the first plurality of external terminals 60. Each of the first plurality of external terminals 60 is a terminal through which a main current flows. Each of the second plurality of external terminals 60 is a control terminal for controlling operation of the plurality of semiconductor elements 30.

In the example shown in FIG. 1, each of the plurality of external terminals 60 is an external terminal 60 that is made of a metallic plate with an L-shape. The external terminal 60 includes a pin 61 and a leg 62.

The pin 61 is a bar-shaped portion of the external terminal 60. The pin 61 is inserted in a terminal hole 51 among the plurality of terminal holes 51. The pin 61 extends in the direction along the Z-axis in the terminal hole 51. The pin 61 has an end in the direction Z1. The end of the pin 61 in the direction Z1 protrudes from an outer wall surface of the housing 50. Thus, the pin 61 includes a terminal portion that protrudes from the outer wall surface of the housing 50. The terminal portion is connected to the substrate (not shown) on which the semiconductor module 10 is disposed. The pin 61 has the other end in the direction Z2. The end of the pin 61 in the direction Z2 is continuous with the leg 62. The shape of the pin 61 is not limited to the example shown in FIG. 1. The shape of the pin 61 may be such that the tip of the pin 61 branches into two parts, for example.

The leg 62 is a plate-shaped portion of the external terminal 60. The leg 62 is arranged along a surface of the spacer 70 facing in the direction Z1. The leg 62 extends from the end of the pin 61 in the direction Z2 toward the inside of the housing 50. The leg 62 includes a portion that is interposed between the housing 50 and the spacer 70, and a pad that is exposed in a space within the housing 50. The pad is coupled to one end of a wire such as a bonding wire (not shown). The other end of the wire is connected to a circuit substrate 20 among the plurality of circuit substrates 20 or to a semiconductor element 30 among the plurality of semiconductor elements 30. These connections cause the external terminal 60 and the semiconductor element 30 to be electrically connected to each other. The wire is wire BW shown in FIG. 4, described below.

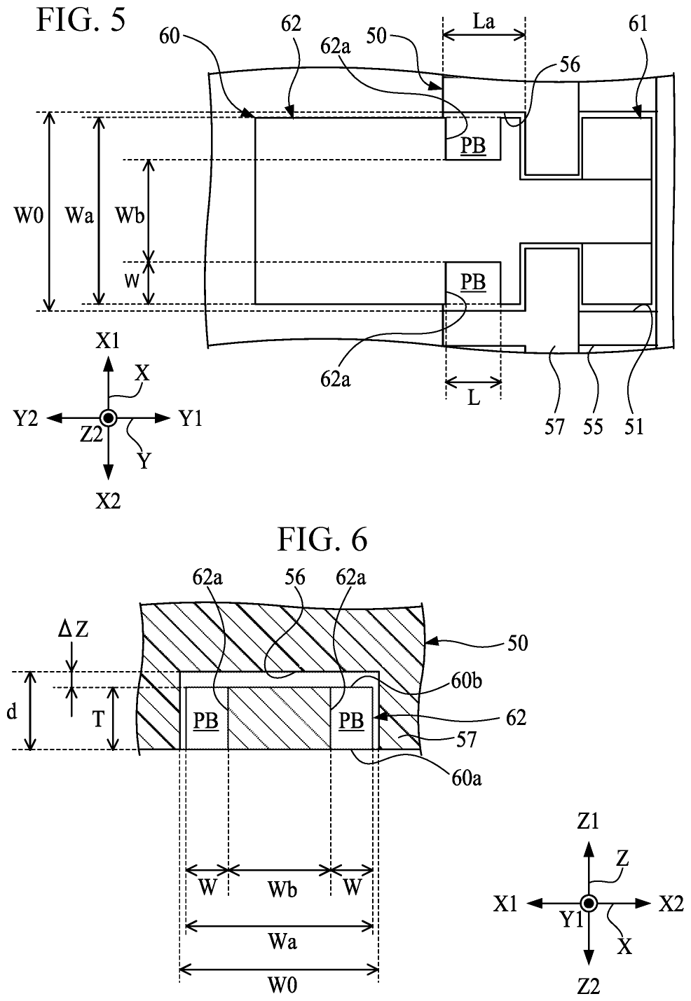

Thus, the external terminal 60 has the plate-shaped leg 62 that is interposed between the housing 50 and the spacer 70. The leg 62 is shaped to cause an adhesive for bonding the housing 50 and the spacer 70 to each other to sufficiently enter a gap between the leg 62 and the housing 50. The leg 62 will be described in detail below with reference to FIG. 5 and FIG. 6.

The spacer 70 is a frame-shaped member that is interposed between the base 40 and the housing 50. The spacer 70 functions to hold the plurality of external terminals 60 toward the housing 50 and to ensure electrical insulation between each of the plurality of external terminals 60 and the base 40. The spacer 70 is substantially an insulator. For example, the spacer 70 is made of a resin material such as a PPS material or a PBT material, etc., as is the housing 50. The resin material may include an inorganic filler such as an alumina material or a silica material, etc., to improve mechanical strength of the spacer 70. The material contained in the spacer 70 is not limited to a resin material. For example, the material contained in the spacer 70 may be a ceramic material.

In the example shown in FIG. 1, a direction of thickness of the spacer 70 is the direction along the Z-axis. The spacer 70 has a surface 70a facing in the direction Z1. The surface 70a of the spacer 70 is bonded by an adhesive to the housing 50. Although not shown in FIG. 1, the adhesive is an adhesive B1 described below. The spacer 70 has a surface 70b facing in the direction Z2. The surface 70b of the spacer 70 is bonded by an adhesive to the base 40. Although not shown in FIG. 1, the adhesive is an adhesive B2 described below. Either in a state in which the plurality of circuit substrates 20 is disposed over the entire area of the base 40 or in a state in which the base 40 is omitted, the surface 70b of the spacer 70 may be bonded by the adhesive to the plurality of circuit substrates 20.

In the example shown in FIG. 1, the spacer 70 has an outer peripheral surface that is provided with a plurality of protrusions 71. The plurality of protrusions 71 are arranged in a circumferential direction of the spacer 70. Thus, it is possible to fit the housing 50 and the spacer 70 to each other such that the spacer 70 can be easily inserted inside the housing 50. The number of protrusions 71, the positions of the protrusions 71, and the shapes of the protrusions 71 are not limited to the examples shown in FIG. 1, and these may be freely selected. Each of the plurality of protrusions 71 may be formed, or may be omitted, as appropriate.

The lid 80 is a plate-shaped member coupled to a surface of the housing 50 facing in the direction Z1. The lid 80 is made of a resin material such as a PPS material or a PBT material, etc., as is the housing 50, for example. The lid 80 is bonded to the housing 50 by an adhesive, etc., such that a gap between the lid 80 and the housing 50 is sealed.

The base 40, the housing 50, and the lid 80 surround a space. The space surrounded by the base 40, the housing 50, and the lid 80 is filled with a potting material that encapsulates the plurality of semiconductor elements 30. Although not shown in FIG. 1, the potting material is a potting material PA described below. The potting material includes, for example, a silicone resin such as a silicone gel material.

In the semiconductor module 10 described above, the housing 50 and the spacer 70 are bonded by the adhesive to each other in a state in which the leg 62 of each of the plurality of external terminals 60 is interposed between the housing 50 and the spacer 70. A gap between the housing 50 and each of the plurality of external terminals 60 is filled with the adhesive. Thus, it is possible to prevent the potting material in the housing 50 from reaching a terminal portion of an external terminal 60 via the gap and a terminal hole 51. This point will be described in detail below.

### 1-2. External Terminals

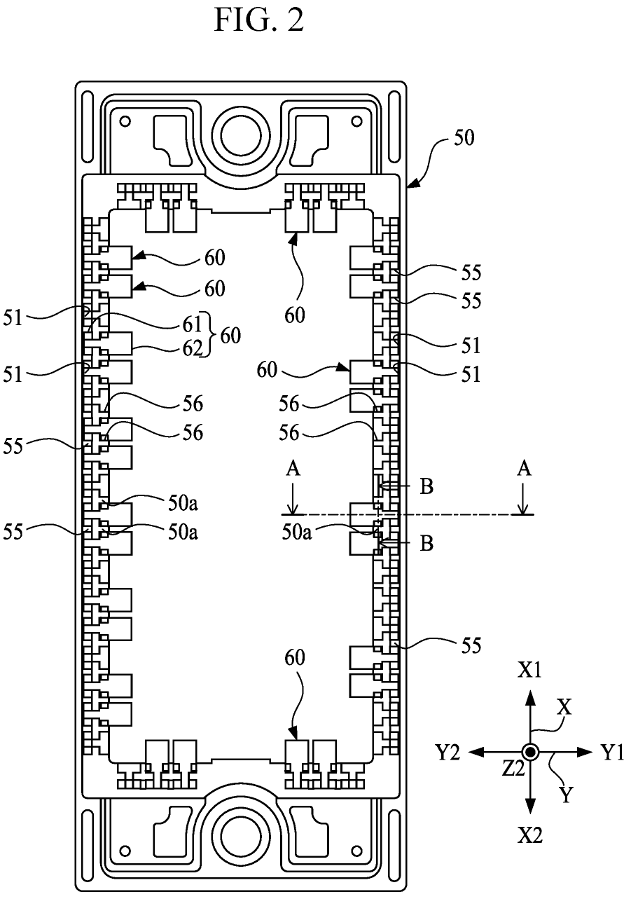

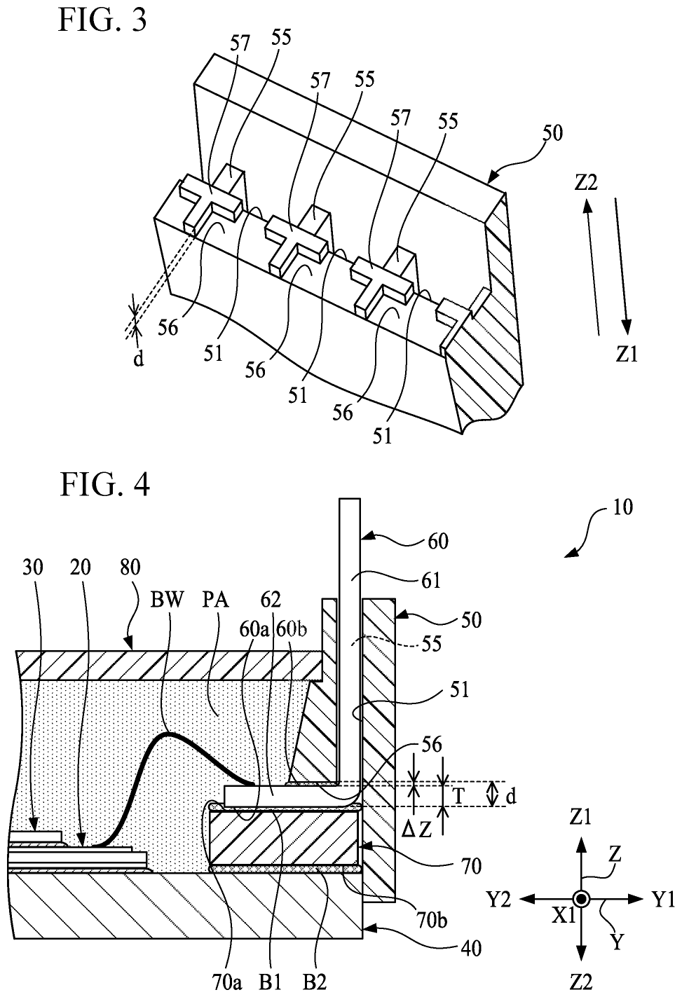

FIG. 2 is a bottom view of the housing 50. In other words, FIG. 2 is a diagram showing the housing 50 equipped with the plurality of external terminals 60 as viewed in the direction Z1. FIG. 3 is a perspective view of a portion of the housing 50. FIG. 3 is a diagram showing the housing 50 as viewed in a direction slightly inclined relative to the direction Z1 for convenience of explanation of a plurality of partitions 55. As shown in FIG. 2 and FIG. 3, the housing 50 is provided with the plurality of partitions 55. Each of the plurality of partitions 55 separates two adjacent terminal holes 51 from each other.

In the example shown in FIG. 2 and FIG. 3, each of the plurality of terminal holes 51 has a shape that corresponds to the shape of the pin 61 of an external terminal 60 among the plurality of external terminals 60. Specifically, each of the plurality of terminal holes 51 includes a first portion and a second portion. The first portion opens to the surface of the housing 50 facing in the direction Z1. The second portion opens to a surface of the housing 50 facing in the direction Z2. The first portion and the second portion are in communication with each other. In this embodiment, the first portion and the second portion are equal to each other in thickness, but the width of the second portion is less than the width of the first portion.

The housing 50 includes a plurality of protrusions 57 and a plurality of recesses 56.

The plurality of protrusions 57 define the plurality of recesses 56. Each of the plurality of protrusions 57 has a top surface that is a plane surface facing in the direction Z2. The top surface is bonded by the adhesive B1 to the surface 70a of the spacer 70. In the example shown in FIG. 2, each of the plurality of protrusions 57 has a T-shape in plan view. In plan view, the shape of each of the plurality of protrusions 57 is not limited to the example shown in FIG. 2. In plan view, the shape of each of the plurality of protrusions 57 may be freely selected.

Each of the plurality of recesses 56 is a recess 56 for accommodating a leg 62. The recess 56 is defined by two adjacent protrusions 57 among the plurality of protrusions 57. The recess 56 extends from a terminal hole 51 among the plurality of terminal holes 51 toward a space within the housing 50. The recess 56 causes the space within the housing 50 and the terminal hole 51 to be in communication with each other. In a state in which an external terminal 60 is inserted in the terminal hole 51 corresponding to the recess 56, a portion of the leg 62 of the external terminal 60 is arranged in the recess 56. In plan view, the shape of the recess 56 conforms to the portion of the leg 62. Thus, the recess 56 regulates a change in position of the external terminal 60.

FIG. 4 is a cross section of the semiconductor module 10 taken along line A-A in FIG. 2. As shown in FIG. 4, the spacer 70 is interposed between the base 40 and the housing 50.

The surface 70a of the spacer 70 is bonded by the adhesive B1 not only to the housing 50, but also to the plurality of external terminals 60. The surface 70b of the spacer 70 is bonded by the adhesive B2 to the base 40.

The adhesive B1 and the adhesive B2 are each an insulating adhesive. More specifically, the adhesive B1 is an epoxy adhesive, an acrylic adhesive, a urethane adhesive, or a silicone adhesive, for example. The adhesive B1 and the adhesive B2 may be of the same type or of a different type. In the example shown in FIG. 4, the adhesive B1 and the adhesive B2 are separated by the spacer 70 from each other. However, the present disclosure is not limited thereto. The adhesive B1 and the adhesive B2 may be contiguous. For example, the adhesive B2 may spread from a gap between the spacer 70 and the base 40 to a gap between the base 40 and the housing 50. In this case, the adhesive B2 not only bonds the base 40 and the spacer 70 to each other, but also bonds the base 40 and the housing 50 to each other. The adhesive B1 and the adhesive B2 may each include an insulating inorganic filler such as an alumina material or a silica material, etc.

The adhesive B1 is preferably a heat curing adhesive. The heat curing adhesive has a property of temporarily softening under heating before being cured. In a state in which the adhesive B1 is a heat curing adhesive, an advantage is obtained in that the adhesive B1 for curing can readily enter the gap between the housing 50 and each of the plurality of external terminals 60. In addition, the heat curing adhesive can be cured at a desired timing. Thus, in a state in which the adhesive B1 is a heat curing adhesive, it is possible to prevent excessive spreading of the adhesive B1.

The adhesive B1 not only bonds the housing 50 and the spacer 70 to each other, but also bonds the housing 50 and the spacer 70 to the leg 62 of each of the plurality of external terminals 60. The leg 62 is accommodated in a recess 56 among the plurality of recesses 56. A gap between a wall surface of the recess 56 of the housing 50 and the leg 62 is filled with the adhesive B1. Although not shown, the adhesive B1 may seal the plurality of terminal holes 51.

As shown in FIG. 4, each of the plurality of external terminals 60 is an external terminal 60 with a leg 62. The leg 62 has a surface 60a facing in the direction Z2, and a surface 60b facing in the direction Z1. The surface 60a is bonded by the adhesive B1 to the surface 70a of the spacer 70. The surface 60b is bonded by the adhesive B1 to a bottom surface of a recess 56 of the housing 50. The surface 60b has a pad that is not covered with the recess 56. This pad is coupled to one end of the wire BW such as a bonding wire.

The depth d of the recess 56 is greater than the thickness T of the leg 62. Thus, even if the depth d of the recess 56 and the thickness T of the leg 62 vary due to manufacturing errors in the recess 56 and in the leg 62, it is possible to arrange the leg 62 in the recess 56. A difference ΔZ between the depth d of the recess 56 and the thickness T of the leg 62 is slightly greater than a value due to manufacturing error in the recess 56 and in the leg 62. The difference ΔZ is not particularly limited. The difference ΔZ is in a range of about 0.01 mm or more and about 0.1 mm or less, for example. The thickness T of the leg 62 is not particularly limited. The thickness T of the leg 62 is, for example, about a 1 mm.

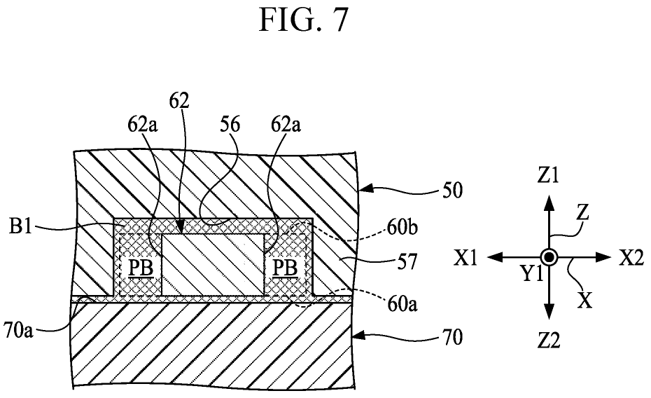

FIG. 5 is a plan view explaining the leg 62 of the external terminal 60 according to the first embodiment. FIG. 6 is a cross section explaining the leg 62 of the external terminal 60 according to the first embodiment. FIG. 7 is a diagram explaining at least one passage PB for the adhesive B1 in the recess 56 of the housing 50 according to the first embodiment. FIG. 5 is a diagram showing a portion of the housing 50 equipped with the plurality of external terminals 60 as viewed in the direction Z1, as in FIG. 2 described above. FIG. 6 is a cross section taken along line B-B in FIG. 2. In FIG. 5 and FIG. 6, the adhesive B1 and the spacer 70 are omitted for convenience.

As shown in FIG. 5, the leg 62 has two side surfaces with two notches 62a. Each of the notches 62a extends in the recess 56 from the surface 60a to the surface 60b. Each of the notches 62a constitutes a passage PB for the adhesive B1. In other words, in the recess 56, a portion of the leg 62 in a direction of length of the leg 62 is provided with the at least one passage PB for the adhesive B1, the at least one passage PB being across the leg 62 in a direction of thickness of the leg 62. The at least one passage PB is constituted of the notches 62a.

The length of each of the notches 62a in a direction of width of the leg 62, which is the width W of the passage PB in the direction of width of the leg 62, is greater than the difference ΔZ between the depth d of the recess 56 and the thickness T of the leg 62. The direction of length of the leg 62 means a direction from a terminal hole, in which an external terminal is inserted, toward the inside of the housing 50. The direction of width of the leg 62 means a direction that is perpendicular not only to the direction of thickness of the leg 62, but also to the direction of length of the leg 62.

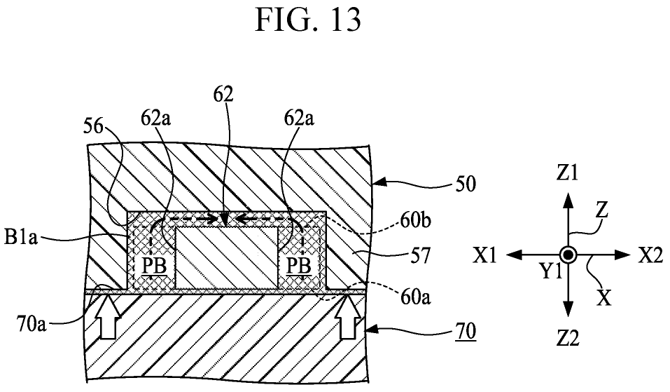

As described above, in the recess 56, the leg 62 is provided with each of the passages PB that has the width W greater than the difference ΔZ, each of the passages PB being across the leg 62 in the direction of thickness of the leg 62. Thus, as shown in FIG. 12 and FIG. 13 described below, when the housing 50 and the spacer 70 are bonded to each other in a state in which the leg 62 is accommodated in the recess 56 of the housing 50, the adhesive B1 can readily enter each of the passages PB. Accordingly, the adhesive B1 passes through each of the passages PB to appropriately flow into a gap between the leg 62 and the bottom surface of the recess 56 of the housing 50. Consequently, as shown in FIG. 7, the adhesive B1 spreads sufficiently over the entirety of the leg 62. Thus, the adhesive B1 can seal the gap between the wall surface of the recess 56 and the leg 62. As a result, it is possible to prevent the potting material PA in the housing 50 from reaching the terminal portion of the external terminal 60 via the gap. In the recess 56, the portion of the leg 62 in the direction of length of the leg 62 is provided with each of the passages PB. Thus, the wall surface of the recess 56 of the housing 50 is partly in contact with the leg 62, resulting in fixing a position of the leg 62.

The adhesive B1, which seals the gap between the wall surface of the recess 56 and the leg 62, may preferably seal a space between the gap and the pin 61 of the external terminal 60. In this case, it is possible to properly prevent the potting material PA in the housing 50 from reaching the terminal portion of the external terminal 60.

In the embodiment shown in FIG. 5, the leg 62 includes a first side surface and a second side surface that are aligned with each other in the direction of width of the leg 62. The first side surface is provided with one of the two notches 62a that is an example of a first notch. The second surface is provided with the other of the two notches 62a that is an example of a second notch. In plan view, each of the two notches 62a is rectangular. The two notches 62a are each arranged in the recess 56. Since the two notches 62a are each arranged in the recess 56, each of the two notches 62a constitutes a passage PB. The side surfaces of the legs 62, except for parts provided with the notches 62a, are along the side surfaces of the recess 56. Thus, the recess 56 fixes the position of the leg 62. As described above, in the recess 56 of the housing 50, the portion of the leg 62 in the direction of length of the leg 62 is provided with each of the passages PB. Thus, the 20) wall surface of the recess 56 of the housing 50 is partly in contact with the leg 62, resulting in fixing the position of the leg 62.

In plan view, the shape of each of the notches 62a is not limited to the example shown in FIG. 5, and may be triangular or semicircular, for example. Each of the notches 62a of the leg 62 may have a side surface that is inclined relative to the Z-axis. The side surface of each of the notches 62a may be bent or may be curved. In other words, areas of cross sections, which are perpendicular to the Z-axis, of a passage PB constituted by each of the notches 62a may not be the same as the others. For example, the areas of the cross sections may be increased in the direction Z1, or alternatively, the areas of the cross sections may be decreased in the direction Z1.

In a configuration in which a passage PB is constituted of a notch 62a, it is possible to provide the passage PB between the wall surface of the recess 56 and the leg 62. Thus, compared to a configuration in which a passage PB is constituted of a through hole that penetrates the leg 62 as in a second embodiment described below, it is possible to substantially prevent formation of a gap, in which no adhesive B1 exists, between the wall surface of the recess 56 and the leg 62.

In this embodiment, as shown in FIG. 5 and FIG. 6, the two notches 62a are aligned with each other in the direction of width of the leg 62. Each of the two notches 62a constitutes a passage PB. Thus, compared to a configuration in which only one notch 62a exists, the adhesive B1 can readily enter the gap between the leg 62 and the bottom surface of the recess 56.

The leg 62 includes the first side surface and the second side surface that are aligned with each other in the direction of width of the leg 62. The first side surface is provided with one of the two notches 62a. The second surface is provided with the other of the two notches 62a. Thus, compared to a configuration in which only one side surface of the first and second side surfaces is provided with only one notch 62a, the adhesive B1 can readily enter the gap between the leg 62 and the bottom surface of the recess 56 uniformly in the direction of width of the leg 62. In addition, compared to a configuration in which a side surface of the leg 62 close to a terminal hole 51 is provided with a notch 62a, the adhesive B1 can readily enter not only the gap between the leg 62 and the bottom surface of the recess 56, but also a gap between the leg 62 and the side surfaces of the recess 56.

In the embodiment shown in FIG. 5, the length L of a passage PB in the direction of length of the leg 62 is greater than the width W of the passage PB in the direction of width of the leg 62. Thus, compared to a configuration in which the length L of a passage PB is less than the width W of the passage PB, the adhesive B1 having been interposed between the leg 62 and the spacer 70 can flow readily into the gap between the leg 62 and the bottom surface of the recess 56 of the housing 50 via each of the passages PB.

The length L of the passage PB may be less than or equal to the width W of each of the passages PB. However, the length L of the passage PB is preferably less than the length La of the recess 56 in the direction of length of the leg 62. In this case, it is possible to provide the leg 62 with the pad having an area required for wire bonding, and it is possible to avoid the leg 62 being large.

The width W of the passage PB is greater than the difference ΔZ. However, if the width W of the passage PB is too small, it is difficult for the adhesive B1 to flow into the gap between the leg 62 and the bottom surface of the recess 56 of the housing 50 via the passage PB, depending on the type of the adhesive B1. If the width W of the passage PB is too large, it is difficult to ensure both required mechanical strength of the leg 62 and electrical conductivity of the leg 62, depending on the thickness T of the leg 62 or depending on the material for the leg 62.

Thus, a relationship 1.1<(L/W)<3.0 is preferably satisfied, in which L is the length of each of the passages PB in the direction of length of the leg 62, and W is the width of each of the passages PB in the direction of width of the leg 62. When this relationship is satisfied, the recess 56 firmly fixes the position of the leg 62, and the adhesive B1 having been interposed between the leg 62 and the spacer 70 can sufficiently flow into the gap between the leg 62 and the bottom surface of the recess 56 of the housing 50 via each of the passages PB.

A relationship 0.2<(W/Wa)<0.4 is preferably satisfied, in which Wa is the width of the leg 62, and W is the width of each of the passages PB in the direction of width of the leg 62. When this relationship is satisfied, required mechanical strength of the leg 62 and electrical conductivity of the leg 62 are ensured, and the adhesive B1 having been interposed between the leg 62 and the spacer 70 can sufficiently flow into the gap between the leg 62 and the bottom surface of the recess 56 of the housing 50 via each of the passages PB.

In contrast, if “W/Wa” is too small, it is difficult for the adhesive B1 to flow into the gap between the leg 62 and the bottom surface of the recess 56 of the housing 50 via each of the passages PB, depending on the type of the adhesive B1. If “W/Wa” is too large, it is difficult to ensure required mechanical strength of the leg 62 and conductivity of the leg 62, depending on the thickness T of the leg 62 or depending on a material for the leg 62.

A relationship 0.5<(W/T)<1.5 is preferably satisfied, in which T is the thickness of the leg 62, and W is the width of each of the passages PB in the direction of width of the leg 62. When this relationship is satisfied, required mechanical strength of the leg 62 is ensured, and the adhesive B1 having been interposed between the leg 62 and the spacer 70 can sufficiently flow into the gap between the leg 62 and the bottom surface of the recess 56 of the housing 50 via each of the passages PB.

### 1-3. Method of Producing Semiconductor Module

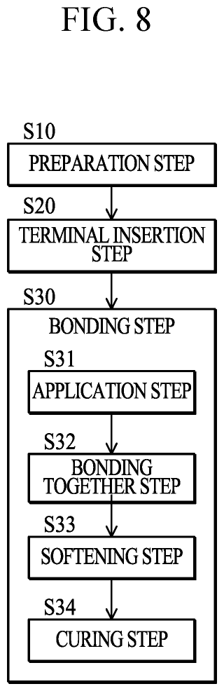

FIG. 8 is a flowchart showing a method of producing the semiconductor module 10 according to the first embodiment. As shown in FIG. 8, the method of producing the semiconductor module 10 includes a preparation step S10, a terminal insertion step S20, and a bonding step S30 in this sequence. The bonding step S30 includes an application step S31, a bonding together step S32, a softening step S33, and a curing step S34 in this sequence. Each of the steps will be described sequentially. Hereinafter, a case will be described in which the adhesive B1 described above is a heat curing adhesive. The softening step S33 may be performed, or may be omitted, as appropriate.

### 1-3-1. Preparation Step

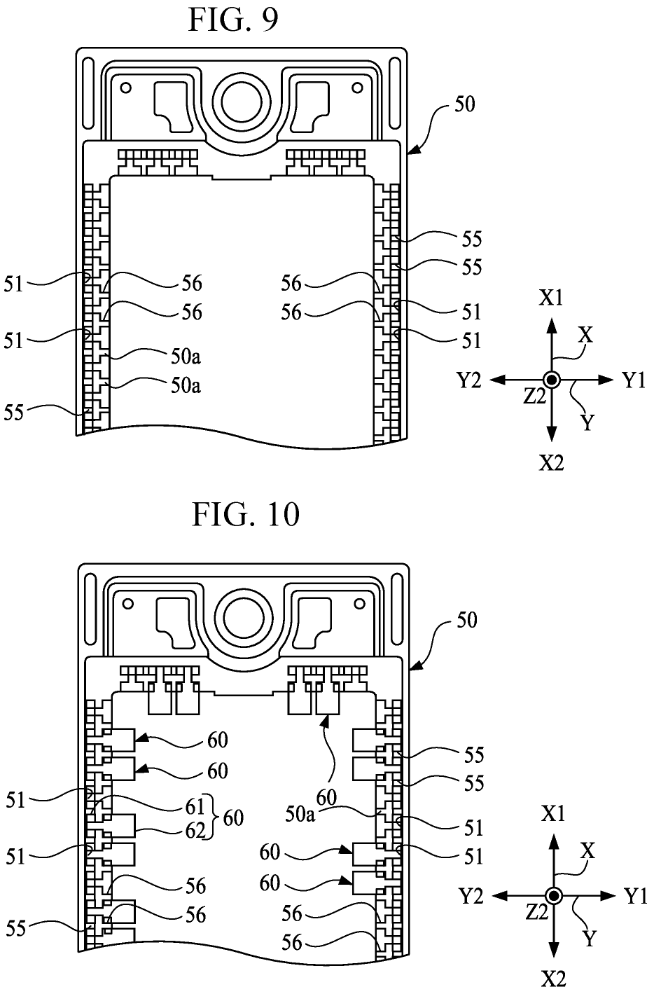

FIG. 9 is a diagram explaining the preparation step S10. FIG. 9 shows a portion of the housing 50 as viewed in the direction Z1. In the preparation step S10, as shown in FIG. 9, the housing 50 is prepared. The housing 50 is formed by injection molding, for example.

Although not shown, in the preparation step S10, the plurality of external terminals 60, the spacer 70, etc., are prepared in addition to the housing 50. Each of the plurality of external terminals 60 is formed by pressing and bending a metallic plate, for example. The spacer 70 is formed by injection molding, for example.

### 1-3-2. Terminal Insertion Step

FIG. 10 is a diagram explaining the terminal insertion step S20. FIG. 10 shows the portion of the housing 50 as viewed in the direction Z1. In the terminal insertion step S20, as shown in FIG. 10, each of the plurality of external terminals 60 is inserted into one of two or more terminal holes 51 among the plurality of terminal holes 51 of the housing 50, and each of the two or more terminal holes 51 is a terminal hole 51 into which an external terminal 60 of the plurality of external terminals 60 is inserted. More specifically, the leg 62 of the external terminal 60 is arranged in a recess 56, and the pin 61 of the external terminal 60 is inserted into the terminal hole 51. At this time, the pin 61 may be fit into the terminal hole 51, and the leg 62 may be fit into the recess 56.

### 1-3-3. Bonding Step

In the bonding step S30, the application step S31, the bonding together step S32, the softening step S33, and the curing step S34 are sequentially performed in the stated order, and the housing 50 and the spacer 70 are bonded by the adhesive B1 to each other.

1-3-3a. Application Step

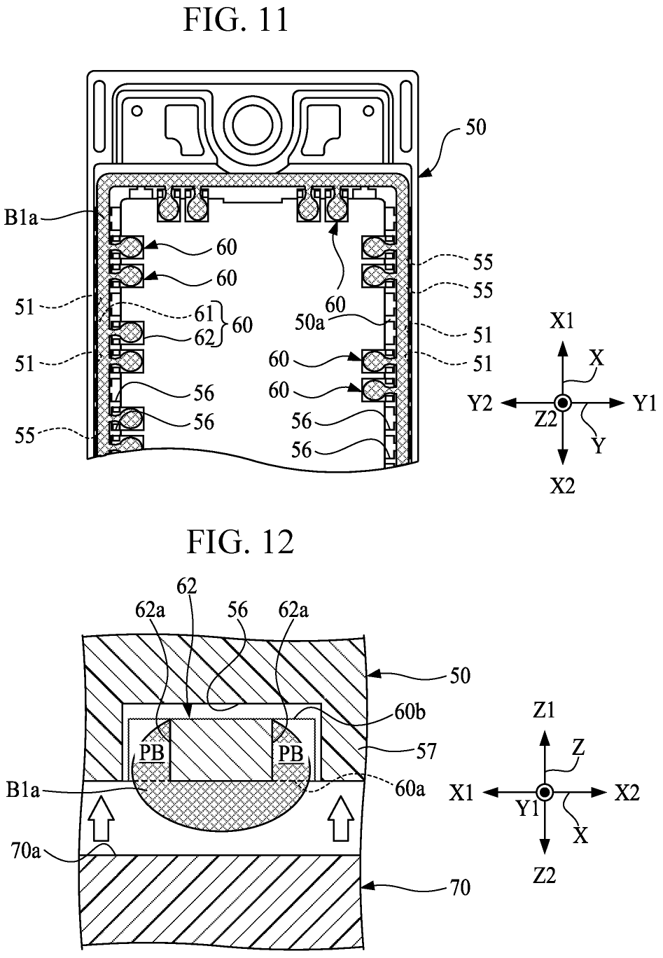

FIG. 11 is a diagram explaining the application step S31 in the bonding step S30. FIG. 11 shows the portion of the housing 50 as viewed in the direction Z1. In the application step S31, as shown in FIG. 11, an adhesive B1a for curing is applied to the surface of the housing 50 facing in the direction Z2. More specifically, after the terminal insertion step S20, in a state in which the direction Z2 is set as an upper direction in the vertical direction, the adhesive B1a for curing is applied to the surface of the housing 50, which faces in the direction Z2, along the circumferential direction of the housing 50 over the entire circumference of the housing 50. The adhesive B1a is applied to both the top surface of each of the protrusions 57 of the housing 50 and the surface 60a of each of the plurality of external terminals 60. The application of the adhesive B1a is performed by use of a dispenser, for example.

In the application step S31, the adhesive B1a may be applied to the surface 70a of the spacer 70. In this case, the application of the adhesive B1a to the top surface of each of the protrusions 57 of the housing 50 may be omitted from the application step S31. An application area of the adhesive B1a in the application step S31 may be partly omitted in the circumferential direction of the housing 50 or in the circumferential direction of the spacer 70 as long as the adhesive B1a can spread, in the bonding together step S32 described below, either over the entire circumference of the housing 50 or over the entire circumference of the spacer 70.

1-3-3b. Bonding Together Step

FIG. 12 is a diagram explaining the bonding together step S32 in the bonding step S30. FIG. 13 is a diagram explaining a function of each of the passages PB for the adhesive B1 in the bonding together step S32 in the bonding step S30. FIG. 12 shows a state in which the housing 50 and the spacer 70 face each other, and are spaced apart from each other, so as to be bonded to each other, by using a cross section corresponding to that shown in FIG. 6 and FIG. 7. FIG. 13 shows a state in which the housing 50 and the spacer 70 are bonded to each other, by using a cross section corresponding to that shown in FIG. 6 and FIG. 7.

In the bonding together step S32 after the application step S31, as shown in FIG. 12, the spacer 70 is pressed toward the housing 50 to which the adhesive B1a is applied. Thus, as shown in FIG. 13, the housing 50 and the spacer 70 are bonded to each other via the adhesive B1a. At this time, the adhesive B1a flows to fill the gap between the wall surface of the recess 56 and the leg 62. As indicated by dashed arrows in FIG. 13, the adhesive B1a enters a gap between the bottom surface of the recess 56 and the surface 60b of the leg 62 via each of the passages PB. Thus, the adhesive B1a for curing spreads sufficiently over the entirety of the leg 62. As a result, the cured adhesive B1 can seal the gap between the wall surface of the recess 56 and the leg 62.

The width W of each of the passages PB is greater than the difference ΔZ as described above. Thus, when the housing 50 and the spacer 70 are bonded to each other in a state in which the leg 62 is accommodated in the recess 56 of the housing 50, the adhesive B1a can readily enter each of the passages PB. In contrast, in a conventional configuration in which no passage PB exists and a gap between the side surface of the leg 62 and the side surface of the recess 56 is substantially a small gap such as a fit tolerance, it is difficult for the adhesive B1a to sufficiently enter the gap between the leg 62 and the bottom surface of the recess 56. Thus, in the conventional configuration, the adhesive B1a may not sufficiently enter the gap between the housing 50 and the leg 62.

1-3-3c. Softening Step

Although not shown, in the softening step S33, the adhesive B1a is softened, resulting in enhancing adhesion of the housing 50 to the spacer 70. Thus, the gap between the housing 50 and each of the plurality of external terminals 60 is properly filled with the adhesive B1a. In the softening step S33, the adhesive B1a is heated to a temperature lower than a curing temperature by use of a heater or an oven, so as to be softened. A processing temperature and a processing time for the softening step S33 are determined depending on the type of adhesive B1a, etc. The processing temperature and the processing time are not particularly limited. The processing temperature and the processing time may be freely selected.

1-3-3d. Curing Step

Although not shown, in the curing step S34 after the softening step S33, the adhesive B1a is further heated to be cured. As a result, the adhesive B1 is formed as a cured product of the adhesive B1a. The curing step S34 may be performed after a predetermined time has elapsed since a point in time of completion of the softening step S33. Alternatively, the curing step S34 may be performed continuously immediately after the softening step S33. When the curing step S34 is performed continuously immediately after the softening step S33, the softening step S33 can be regarded as a part of the curing step S34. In other words, the softening step S33 may overlap the curing step S34.

Although not shown, after the curing step S34, the base 40 on which the plurality of circuit substrates 20 is disposed is bonded by the adhesive B2 to the spacer 70. Thereafter, wires BW are coupled by ultrasonic bonding, etc., to the legs 62 and the plurality of circuit substrates 20 so as to electrically connect the plurality of external terminals 60 and the plurality of semiconductor elements 30 to each other. Thereafter, the potting material PA is injected into the housing 50, and then the lid 80 is bonded by an adhesive, etc., to the housing 50. Thus, the semiconductor module 10 is produced.

When the potting material PA is injected into the space surrounded by both the base 40 and the housing 50 in a state in which a gap is present between the leg 62 of an external terminal 60 and the housing 50, the potting material PA may reach the terminal portion of the external terminal 60 via the gap. In this case, the external terminal 60 cannot be electrically connected to a substrate on which the semiconductor module 10 is disposed.

In contrast, in the semiconductor module 10, as described above, the adhesive B1 can seal the gap between the wall surface and the bottom surface of the recess 56 and the leg 62. As a result, it is possible to prevent the potting material PA in the housing 50 from reaching the terminal portion of the external terminal 60 via the gap.

### 2. Second Embodiment

A second embodiment according to the present disclosure will now be described below. In the configuration described below, elements relating to actions and functions that are the same as those in the embodiment described above will be denoted by the same reference signs used in the description of the embodiment described above, and detailed description thereof will be omitted as appropriate.

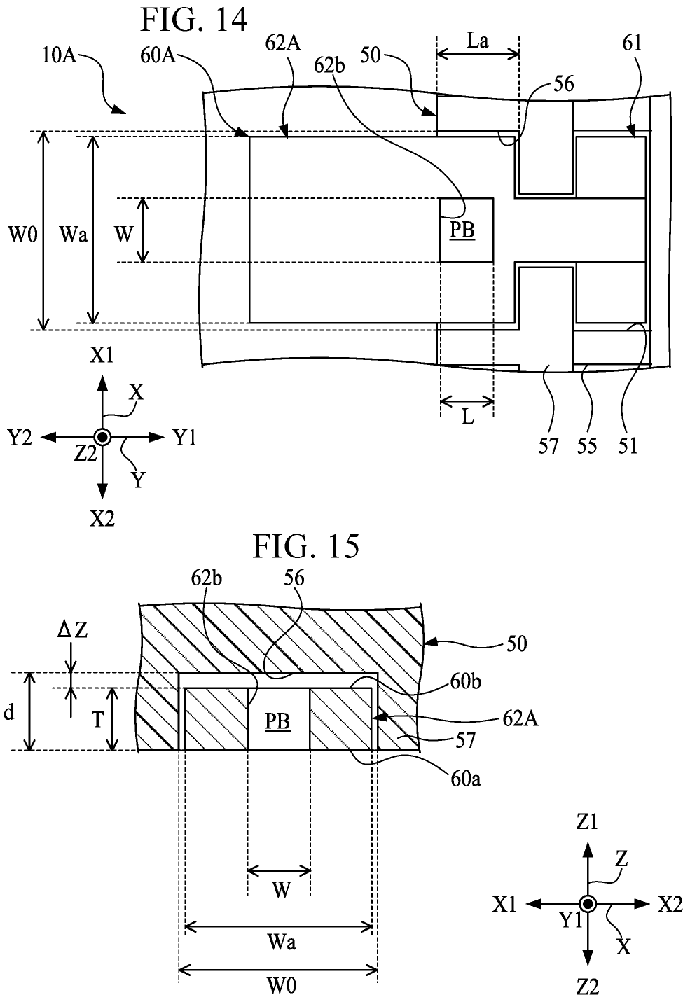

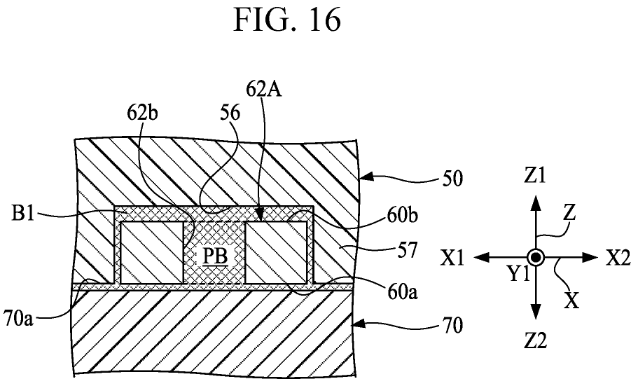

FIG. 14 is a plan view explaining a leg 62A of an external terminal 60A according to the second embodiment. FIG. 15 is a cross section explaining the leg 62A of the external terminal 60A according to the second embodiment. FIG. 16 is a diagram explaining a passage PB for the adhesive B1 in a recess 56 of the housing 50 according to the second embodiment. In FIG. 14 and FIG. 15, the adhesive B1 and the spacer 70 are omitted for convenience.

In the second embodiment, a semiconductor module 10A is configured in the same manner as the semiconductor module 10 according to the first embodiment, except for a plurality of external terminals 60A in place of the plurality of external terminals 60 according to the first embodiment. Each of the plurality of external terminals 60A is configured in the same manner as each of the plurality of external terminals 60 according to the first embodiment, except for the leg 62A in place of the leg 62 according to the first embodiment.

As shown in FIG. 14 and FIG. 15, the leg 62A is configured in the same manner as the leg 62 according to the first embodiment, except for a through hole 62b in place of the two notches 62a according to the first embodiment.

The through hole 62b extends in the recess 56 from the surface 60a to the surface 60b. The through hole 62b constitutes the passage PB for the adhesive B1. In other words, in the recess 56, a portion of the leg 62A in a direction of length of the leg 62A is provided with at least one passage PB for the adhesive B1, the at least one passage PB being across the leg 62A in a direction of thickness of the leg 62A. The at least one passage PB is constituted of the through hole 62b.

The length of the through hole 62b in a direction of width of the leg 62A, which is the width W of the passage PB in the direction of width of the leg 62A, is greater than the difference ΔZ between the depth d of the recess 56 and the thickness T of the leg 62A. In a configuration in which the passage PB is constituted of the through hole 62b, the adhesive B1 passes through the passage PB to appropriately flow into a gap between the leg 62A and the bottom surface of the recess 56 of the housing 50. Consequently, the adhesive B1 spreads sufficiently over the entirety of the leg 62A. Thus, the adhesive B1 can seal the gap between the wall surface of the recess 56 and the leg 62A.

In the embodiment shown in FIG. 14 and FIG. 15, a central portion of the leg 62A in the direction of width of the leg 62A is provided with the through hole 62b. In plan view, the through hole 62b is rectangular. The through hole 62b is arranged in the recess 56. Since the through hole 62b is arranged in the recess 56, the through hole 62b constitutes the passage PB. The side surfaces of the leg 62A are along the side surfaces of the recess 56. Thus, the recess 56 fixes a position of the leg 62A.

In plan view, the shape of the through hole 62b is not limited to the example shown in FIG. 14, and it may be triangular or semicircular, for example. In addition, areas of cross sections, which are perpendicular to the Z-axis, of the through hole 62b may not be the same. In other words, areas of cross sections, which are perpendicular to the Z-axis, of the passage PB constituted by the through hole 62b may not be the same. For example, the areas of the cross sections may be increased in the direction Z1, or alternatively, the areas of the cross sections may be decreased in the direction Z1.

According to the second embodiment as described above, the adhesive B1 spreads sufficiently over the entirety of the leg 62A. Thus, the adhesive B1 can seal the gap between the wall surface of the recess 56 and the leg 62A. As a result, it is possible to prevent the potting material PA in the housing 50 from reaching the terminal portion of the external terminal 60 via the gap.

In the second embodiment described above, the leg 62A is provided with the through hole 62b penetrating the leg 62A in the direction of thickness of the leg 62A, and the through hole 62b constitutes the passage PB. Compared to a configuration in which the passage PB is constituted of the notch 62a according to the first embodiment, a configuration in which the passage PB is constituted of the through hole 62b has not only an advantage in that mechanical strength of the leg 62A is enhanced, but also an advantage in that the position of the leg 62A is readily fixed by the wall surface of the recess 56 of the housing 50. The leg 62A has one through hole 62b in the second embodiment. However, the leg 62A may have two or more through holes 62b. In addition, the leg 62A may have the notch 62a according to the first embodiment.

### 3. Modifications

The present disclosure is not limited to the embodiments described above, and various modifications described below can be made thereto. In addition, each of the embodiments and each of the modifications may be combined with others as appropriate.

### 3-1. First Modification

In the embodiments described above, a configuration is described in which one or two passages PB exist. However, the present disclosure is not limited thereto. Three or more passages PB may exist.

Specifically, in the first embodiment, a configuration is described in which the leg 62 is provided with the two notches 62a; however, the leg 62 may be provided with only one notch 62a or with three or more notches 62a. The dimensions of the notches 62a may be different from each other.

In the second embodiment, a configuration is described in which the leg 62A is provided with one through hole 62b; however, the leg 62A may be provided with two or more through holes 62b. The dimensions of the through holes 62b may be different from each other.

### 3-2. Second Modification

In the first embodiment, a configuration is described in which the two notches 62a are aligned with each other in the direction of width of the leg 62. However, the present disclosure is not limited thereto. For example, the two notches 62a may be apart from each other in the direction of length of the leg 62.

### 3-3. Third Modification

In the first embodiment, a configuration is described in which the leg 62 includes the first side surface and the second side surface that are aligned with each other in the direction of width of the leg 62, and the first side surface is provided with one of the two notches 62a, and the second surface is provided with the other of the two notches 62a. However, the present disclosure is not limited thereto. For example, a side surface of the leg 62 close to a terminal hole 51 may be provided with at least one notch 62a.

### 3-4. Fourth Modification

In the embodiments described above, a configuration is described in which the spacer 70 is the holding member. However, the present disclosure is not limited thereto. For example, in a configuration in which the spacer 70 is omitted, the base 40 may be the holding member. In this case, to electrically isolate the base 40 from the leg 62 of each of the plurality of external terminals 60, the base 40 may have an insulating portion that is bonded at least to the leg 62.

### DESCRIPTION OF REFERENCE SIGNS

10 . . . semiconductor module, 10A . . . semiconductor module, 20 . . . circuit substrate, 30 . . . semiconductor element, 40 . . . base, 41 . . . mounting hole, 50 . . . housing, 51 . . . terminal hole, 55 . . . partition, 56 . . . protrusion, 57 . . . recess, 60 . . . external terminal, 60A . . . external terminal, 60a . . . surface, 60b . . . surface, 61 . . . pin, 62 . . . leg, 62A . . . leg, 62a . . . notch, 62b . . . through hole, 70 . . . spacer (holding member), 70a . . . surface, 70b . . . surface, 71 . . . protrusion, 80 . . . lid, B1 . . . adhesive, B1a . . . adhesive, B2 . . . adhesive, BW . . . wire, PA . . . potting material, PB . . . passage, S10 . . . preparation step, S20 . . . terminal insertion step, S30 . . . bonding step, S31 . . . application step, S32 . . . bonding together step, S33 . . . softening step, S34 . . . curing step, T . . . thickness, W . . . width, d . . . depth.

What is claimed is:

1. A semiconductor module comprising:
a semiconductor element;
a housing for housing the semiconductor element, the housing including a terminal hole;
an external terminal inserted in the terminal hole, the external terminal being electrically connected to the semiconductor element;
a holding member bonded by an adhesive to the housing; and
a potting material with which the housing is filled,
wherein the external terminal includes a plate-shaped leg interposed between the housing and the holding member,
wherein the housing includes a recess for accommodating the leg,
wherein the recess has a depth greater than a thickness of the leg,
wherein, in the recess, a portion of the leg in a direction of length of the leg is provided with at least one passage for the adhesive, the at least one passage being across the leg in a direction of thickness of the leg, and
wherein a width of the at least one passage in a direction of width of the leg is greater than a difference between the depth of the recess and the thickness of the leg.

2. The semiconductor module according to claim 1, wherein the leg has side surfaces provided with at least one notch constituting the at least one passage.

3. The semiconductor module according to claim 2,
wherein the at least one notch includes a first notch and a second notch that are aligned with each other in the direction of width of the leg,
wherein the at least one passage includes a first passage and a second passage,
wherein the first notch constitutes the first passage, and
wherein the second notch constitutes the second passage.

4. The semiconductor module according to claim 3,
wherein the side surfaces of the leg include a first side surface and a second side surface that are aligned with each other in the direction of width of the leg,
wherein the first side surface is provided with the first notch, and
wherein the second side surface is provided with the second notch.

5. The semiconductor module according to claim 1,
wherein the leg is provided with at least one through hole penetrating the leg in the direction of thickness of the leg, and
wherein the at least one through hole constitutes the at least one passage.

6. The semiconductor module according to claim 2, wherein a length of the at least one passage in the direction of length of the leg is greater than a width of the at least one passage in the direction of width of the leg.

7. The semiconductor module according to claim 6, wherein a relationship 1.1<(L/W)<3.0 is satisfied, where L is the length of the at least one passage in the direction of length of the leg, and W is the width of the at least one passage in the direction of width of the leg.

8. The semiconductor module according to claim 2, wherein a relationship 0.2<(W/Wa)<0.4 is satisfied, where Wa is the width of the leg, and W is the width of the at least one passage in the direction of width of the leg.

9. The semiconductor module according to claim 2, wherein a relationship 0.5<(W/T)<1.5 is satisfied, where T is the thickness of the leg, and W is the width of the at least one passage in the direction of width of the leg.
